(19) United States
(12) Patent Application Publication
(10) Pub. No.: US 2013/0065358 A1
(43) Pub. Date: Mar. 14, 2013

(54) Method for Producing (Electro) Luminescent, Photoactive or Electrically (Semi) Conducting Polymers

(71) Applicants: Matthias Rehahn, Fuerth (DE); Thorsten Schwalm, Darmstadt (DE); Stefan Immel, Darmstadt (DE); Serena Nickel, Darmstadt (DE)

(72) Inventors: Matthias Rehahn, Fuerth (DE); Thorsten Schwalm, Darmstadt (DE); Stefan Immel, Darmstadt (DE); Serena Nickel, Darmstadt (DE)

(73) Assignee: Technische Universitat Darmstadt, Darmstadt (DE)

(21) Appl. No.: 13/510,463

(22) PCT Filed: Nov. 19, 2010
(86) PCT No.: PCT/EP2010/067837

§ 371 Date: Oct. 5, 2012

(30) Foreign Application Priority Data
Nov. 19, 2009 (DE) 10 2009 054 023.7

(51) Int. Cl. C08G 65/00; H01L 51/56

(52) U.S. Cl. 438/99; 522/181; 257/E51.026

(57) ABSTRACT

The invention concerns the production of poly(arylene-vinylenes) and related polymers whose polymerization is triggered photochemically. For that purpose, the low molecular starting materials are firstly cooled to temperatures which are so low that in fact their activation into mostly chinoid intermediate stages (the “active” monomer) occurs; the thermally induced polymerization, however, either does not occur or barely takes place at all. The polymerization is instead triggered in a separate step by means of electromagnetic radiation of a suitable wavelength—either using the absorption behavior of the low-molecular starting compounds/the monomers, or mediated by means of photoinitiators and/or sensitizers.

By way of example, with this method a display is suitable to be coated with poly(arylene-vinylenes). The monomer is hereby deposited. The polymer is subsequently produced in a photo-induced manner. The remaining monomer is washed out. The process takes place at low temperatures.

The present invention concerns a novel manner of production, in particular of (electro)luminescent, photoactive and/or electrically (semi)conducting (hereinafter summarily referred to in brief as “semiconducting”) polymers in or made of solution and/or, for example, on planar, structured, geometrically complex or dispersive carriers. By means of the new production method for the semiconducting polymers, new methods for the deposition of the polymers suitable to be produced in this way on carrier substrates are enabled, which also constitute a subject matter of the invention. This, in turn, allows for semiconducting polymers which were either unusable or only usable in a limited manner, e.g. due to their insolubility and/or infusibility, to be installed in, for example, organic electronic components, namely in displays, light emitting diodes (OLEDs), thin-layer transistors (O-TFTs, OFETs), solar cells (photovoltaic, PV) or circuit boards.

### DESCRIPTION OF, AND INTRODUCTION TO, THE GENERAL FIELD OF THE INVENTION

The invention concerns a manner of production of semiconducting polymers, in particular but not exclusively in accordance with the sense of the specification from above/of production, in particular but not exclusively of semiconducting polymers in the sense as defined above. The manner of producing these polymers according to the present invention comprises the polymerization triggered by electromagnetic radiation of a suitable wavelength (hereinafter referred to as “photo-induced”) of one type or several types of monomers simultaneously or consecutively—as a common characteristic, these monomers comprise a chinoid structure as explained below—into polymers which, in general, can be classified as poly(arylene-vinylenes).

The production of these polymers according to the present invention is possible in or made of homogenous solution, as precipitation polymerization, or by depositing the formed polymers on carrier substrates. Insoluble and/or infusible polymers are hereby also suitable to be used in a controlled application on, for example, a prepared (e.g. pre-structured) carrier (e.g. glass, polymer film, electrode, etc.), which is subsequently suitable to be part of an organic electronic component. The manner of production of the (semi)conducting polymers according to the present invention is particularly suitable to be used in printing processes.

### STATE OF THE ART

In U.S. Pat. No. 6,861,091 B2, poly(p-phenylene-vinylenes) (PPV) are used as electroluminescent polymers. Prior to its installation in the component, the polymer is hereby produced via thermally induced polymerization or via induced polymerization using material initiators and subsequently deposited on the carrier substrate by means of a process such as spin coating. In the US application, the following were cited as other methods for depositing a polymer on a carrier: dip or spray coating, inkjet printing. For all of these methods, the polymer must be deposited on a carrier while dissolved in a solvent, and the solvent must then be removed via vaporization. In order for the polymer to show the necessary solubility for these processing methods despite its restricted chain dynamics, flexible side chains (e.g. alkyl or alkoxy chains, typically with 10 or more carbon atoms) are attached to it—following the concept of the chemically connected solvent—for the purpose of solubilization.

Furthermore, in U.S. Pat. No. 7,135,241 B2 an electroluminescent block copolymer is described which carries long silylated alkyl groups (e.g. C₈HₓR_{y}). These alkyl groups also serve the purpose of being suitable to apply the polymer to the carrier in its dissolved state.

In WO 2004/100282 A2, a method is described wherein a polymer with polymerizable side groups is also applied to the carrier. In addition, a photochemical cross-linking subsequently occurs via the polymer's side groups; this cross-linking makes the polymer film insoluble. Besides stabilizing the layers a photostructuring of the layers is also possible via this cross-linking. DE 10318096 also describes the production of PPVs.

All of the methods mentioned have the disadvantage that they are limited in the sense that a complete polymer in its essential components and formed beforehand is always deposited on the carrier. This can be laborious and restrictive in this respect, because the polymer must be available for its processing/treatment in solution or at least in the form of dispersion with particles capable of forming a film. Only then it is suitable for the substrate to subsequently be coated with a film from this polymer according to the requirements. However, in order for the polymer to dissolve, solubilizing substituents (e.g. alkyl or alkoxy chains, typically with 10 or more carbon atoms) and, for example, photochemically cross-linkable groups for the subsequent stabilization of the films must almost always be introduced to the monomer in the case of semiconducting polymers.

Lateral substituents on semiconducting polymers are also to be used beyond their solubilization function and subsequent cross-linking in order to specifically adjust the electronic properties of the polymers and their intramolecular and intermolecular interactions. However, if side chains are already mandatory just to guarantee the solubility of the polymers, this can lead to the disadvantageous situation that the possibilities of substituting the chromophoric system are more narrowly limited than is beneficial to attaining the electronic properties of the polymer in the device which are actually being aimed for. The case may be, for example, that the functional elements of the semiconducting polymer become highly diluted via the solubilizing substituents, so that electronic and/or optical properties become sub-optimal. Another, often highly undesirable side-effect of solubilizing substituents is the lowering of the glass temperature of the polymer due to the fact that it advances aging and fatigue processes. For this reason, the polymer layers are not just chemically fragile, but thermally and mechanically fragile as well, which may lead to the more rapid aging, fatiguing and failure of the entire component. As a result of this, the lateral substituents also frequently lead to negative consequences, namely that they instigate a so-called microphase separation from the main chains. Through this, the electronic properties of the functional layers (e.g. emission color of an OLED, electron and hole mobilities, injection characteristics) are suitable to clearly change. Finally, there is another problem associated with the solubilizing side chains, namely that it is difficult to deposit several layers of functional polymers on top of one another without leading to swelling and undesired changes in the existing layers when applying each new layer. In many cases—and not always with the desired success—only the subsequent cross-linking of the deposited layers is therefore recommended for that reason prior to the deposition of the next respective layer.

### AIM

The aim of the present invention is to overcome the disadvantages of the state of the art via a new method of production, in particular but not limited to semiconducting polymers. For that purpose, it had to become possible to produce the polymers and deposit them on a carrier substrate (e.g. prepared display substrate, coated glass, polymer film etc.) whilst remaining independent from the solubility of the semiconducting polymer, i.e. without the availability of solubilizing side chains on monomer and polymer.

### ACHIEVEMENT OF THIS AIM

The aim is achieved by means of a completely novel conception of the method for the synthesis of semiconducting polymers. This enables, inter alia, the polymers to be immediately produced during their deposition on the carrier from the monomer(s). This facilitates the production of components from semiconducting polymers, regardless of whether they still show recognizable solubility or not as finished polymers. The core of the method according to the present invention is therefore not necessarily to have to process the semiconducting polymer into the component at the finished polymer stage, but to be able to instead carry out this step with the monomers or their precursors (starting materials). This approach profits from the fact that the solubility of small molecules—in this case the monomers or their precursors—is almost always very good regardless of the existence of solubilizing side groups, meaning that processing of these molecules from, for example, solution or dispersion thereby does not present a problem.

In order for this improved solubility behavior for processing—e.g. the production of an electronic organic component—to be suitable to be utilized, it has to be achieved to prevent the polymerization reaction up to a point following the coating of the carrier substrate, and only then (i.e. at exactly the desired point) be triggered by means of an external stimulus. In the context of the approach according to the present invention described here, the polymerization reaction is caused via electromagnetic radiation (photo-induced). In contrast to the likewise fundamentally possible polymerization via temperature increase, this method, by way of example, also offers the advantage of only triggering the polymerization process in highly defined areas of a layer. In doing so, this offers the chance to structure the semiconducting layers. Furthermore, multi-layer systems are suitable to be produced more simply, namely for example without an additional subsequent cross-linking reaction, by using the low solubility or lack of solubility of the polymer layers ultimately produced, as well as gaining more control over the problems associated with microphase separation.

It must therefore be determined that photo-induced polymerization in the method according to the present invention does not just take place in or from homogeneous solution or in dispersions, but, for example, also following the application of the dissolved/dispersed monomer or its precursor on the prepared carrier substrate. Depending on the solubility of the resulting polymer, this is either deposited as a thin film on the carrier immediately or after evaporation of the solvent. Furthermore, the use of a photomask makes it possible to selectively photopolymerize only defined areas. The polymer then only forms in these exposed areas and is deposited on the substrate. The remaining monomer is not polymerized, and the unexposed areas thereby remain uncoated. Furthermore, the excess monomer is in solution there and can be washed off.

This method is suitable to be applied to all currently known monomers and monomers to be derived from these monomers, which comprise the characteristics specified below. Moreover, the special advantage of this method is that monomers are used which either do not comprise any side chains or that only comprise short (C1 to C10) or few side chains. The use of solubilizing side chains is therefore possible, but not imperative for the success of the method. In addition to the state of the art, this thereby also provides the opportunity of forming monomers (with regard to their substituents) solely for electronic requirements. However, particular significance no longer has to be placed upon ensuring a sufficient level of solubility for subsequent processing. The functional side chains which are suitable to attain a higher weight by means of the method according to is the present invention also include, for example, individual groups which exert an influence on the chromophore system via the effect of the acceptor (e.g. —CN) or donor (e.g. —OR, —NR₂). The introduction of substituents for cross-linking, as is partially the case in the state of the art, is not strictly necessary with this method; however, it is likewise not ruled out.

### GENERAL DESCRIPTION OF THE COMPOUNDS AND THE METHOD

The active monomers (including but not limited to halomethylene-substituted aromatic compounds and heteroaromatic compounds) required for the method according to the present invention are produced in one of the preceding photo-induced polymerization steps via, for example, the dehydrohalogenation of suitable precursors (starting materials including but not limited to double halomethylene-substituted aromatic compounds and heteroaromatic compounds). In addition to the double halomethylene-substituted aromatic compounds which are typically used as starting compounds for Gilch and halogen routes to the poly(arylene-vinylenes), starting compounds used for Gilch-analog reactions to the poly(arylene-vinylenes), e.g. Wessling, sulfinyl, sulfonyl, xanthate route, are, in principle, accessible for the method according to the present invention. The further illustration of the method is therefore intended to be exclusively explained for (but is nevertheless in no way limited to) the example of relevant compounds and reactions for the Gilch reaction.

The dehydrohalogenation of the respective starting compounds (starting materials) is normally carried out via base. Alkali metal hydroxides (e.g. NaOH, KOH), alkali metal hydrides (e.g. NaH, KH), alkali metal alcoholates (e.g. NaOEt, KOEt, NaOMe, KOMe, KOtBu), metal organyls (e.g. MeLi, nBuLi, sBuLi, tBuLi, PhLi) and organic amines (e.g. LDA, DBU, DMAP, pyridine) are, by way of non-exhaustive example, suitable as bases.

Bishalomethylene-substituted aromatic compounds and heteroaromatic compounds are, by way of non-exhaustive example, used as starting materials, wherein the aromatic compound or heteroaromatic compound comprises structures such as, by way of non-exhaustive example, phenyl (I), biphenyl (II), fluorene (III), stilbene (IV), alpha-phenylcinnamonitrile (V), 3-amino-2,3-diphenyl-acrylonitrile (VI), alpha,beta-diphenylfumaronitrile (VII), thienyl (VIII), naphtyl (IX), triazine, triazole, oxadiazole, pyridine, and quinoline.

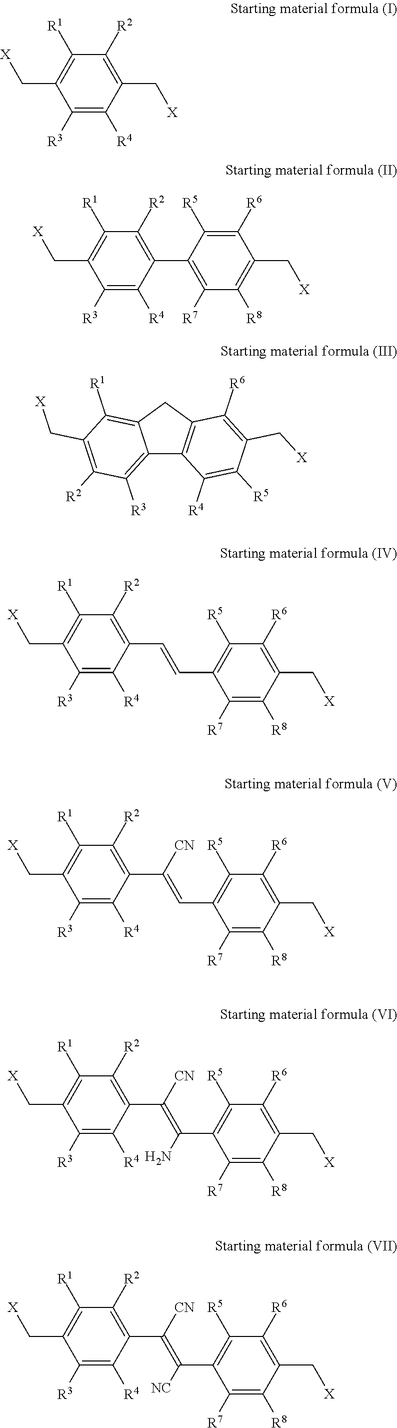

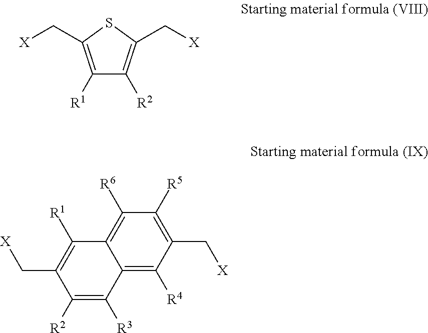

By way of non-exhaustive example, —H, —CH₃, alkyl, alkoxy, aryl, aryloxy; acceptors such as —CN, —SCN, —N⁺(R⁹)₃ (e.g. halide, dicyanamide, CN⁻, bis(trifluoromethylsulfonyl)amide); donors such as —N(R⁹)ₙ, wherein n=1 to 2 and R⁹═H, methyl, ethyl, n-propyl, isopropyl, 1-butyl, 2-butyl, tert-butyl;

—OR¹⁰ oder —R¹⁰, wherein

R¹⁰=linear or branched alkyl (methyl, ethyl, n-propyl, iso-propyl, n-butyl, iso-butyl, sec-butyl, tert-butyl, n-pentyl, iso-pentyl, sec-pentyl, neo-pentyl, 1,2-dimethylpropyl, iso-amyl, n-hexyl, iso-hexyl, sec-hexyl, n-heptyl, iso-heptyl, n-octyl, n-decyl, 1-nonyl, 1-decyl),

R¹⁰=aryl (e.g. phenyl, biphenyl, fluorene, pyrene, tolyl, mesityl, cyclopentadienyl, naphthalene, anthracene),

R¹⁰=heteroaryl (e.g. pyridyl, thiophene, pyrazole, imidazole, carbazole, oxadiazole, furyl)

are used as substituents R¹, R², R³, R⁴, R⁵, R⁶, R⁷, R⁸ and in combinations.

X is usually a —S⁺(Me)₂Cl⁻, trifluoromethanesulfonate, aryl sulfonate, —SR¹⁰, —OR¹⁰ or a halogen, e.g. chlorine, bromine, iodine.

Gilch polymerization takes place using double halomethylene-substituted aromatic compounds such as 1, which are converted into the actual active monomer, a quinodimethane derivative such as 2, under influence of the base used.

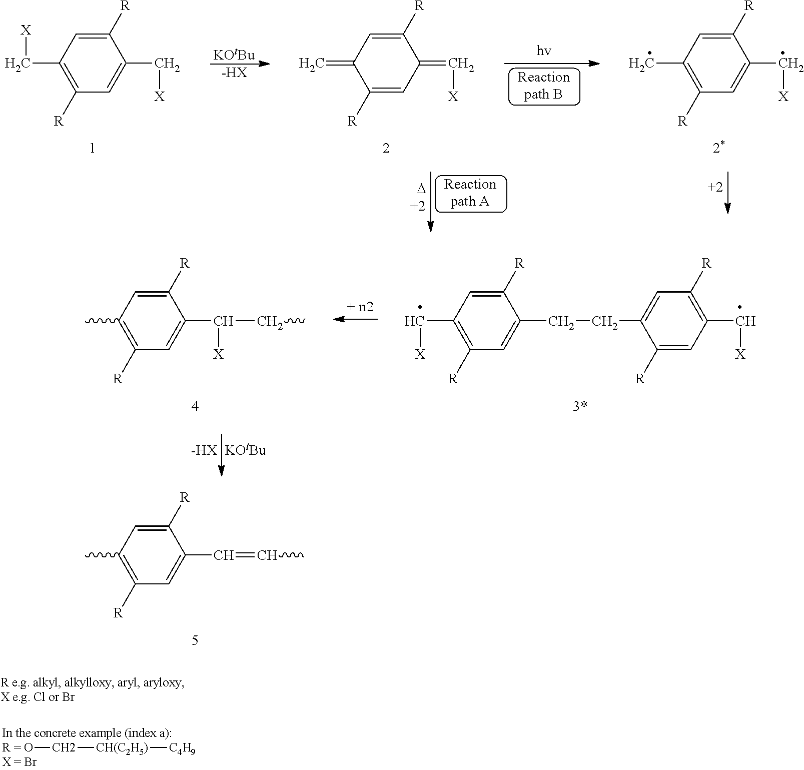

Normally, the active monomer 2 formed in this way is normally reacted shortly after its formation either in the sense of the thermally activated formation of one of the diradicals 3*, which initiates the radical polymerization (reaction path A), or via the connection to radicals formed in the sense of a chain growth via the intermediate 4 to the completed poly(arylene-vinylene) 5. It was surprisingly found that in reactions such as the Gilch reaction, the elimination of HX from the starting material 1 (starting material e.g. bishalomethylene-substituted aromatic compounds or heteroaromatic compounds) is suitable to be carried out at low temperatures—typically but not limited to −30 to −200° C., preferably −50° C. to −200° C., particularly preferably −80° C. to −200° C., in particular −90° C. to −120° C., without this immediately leading to the initiation of a thermal polymerization according to reaction path A and thereby to the reaction via 3* and 4 to 5.

This has the decisive advantage that under these conditions (e.g. at temperatures of −30° C. to −200° C., preferably −60° C. to −200° C., particularly preferably −70° C. to −200° C., in particular −90° C. to −200° C.), the active monomers (quinodimethane species such as 2, generally the simply HX-eliminated intermediates from the aromatic compounds and heteroaromatic compounds used as starting compounds) are initially frequently (almost quantitatively) suitable to be produced and subsequently processed as such, e.g. suitable to be deposited on a carrier substrate (e.g. via established print and coating methods). Polymerization via the irradiation of the solution or dispersion with electromagnetic radiation of a suitable wavelength is subsequently carried out. This radiation triggers a chain growth. At suitable wavelengths, an electronic stimulation of the monomer molecules is suitable to be brought about; in doing so, this subsequently triggers a so-called is “photo-induced polymerization” also at such temperatures which are locally still under the critical temperature for a thermal start. These are typically (but not exclusively) low temperatures, at −30 to −200° C., preferably −50° C. to −200° C., particularly preferably −80° C. to −200° C., in particular −90° C. to −120° C. Electromagnetic radiation, which is suitable for this method, typically (but not exclusively) has wavelengths of 150 nm to 700 nm, preferably from 250 nm to 500 nm. The advantage of photo-induced polymerization is that the polymer immediately forms, i.e. from 1 second to 15 minutes, at the low temperatures specified. For thermal polymerization, a waiting period of more than 30 minutes or an increase in temperature, e.g. to above 0° C., is necessary.

It is supposed, but is not yet able to be considered certain from a scientific perspective, that the polymerization carried out under influence of this irradiation follows the course described via “reaction path B” in the diagram above, namely that the production of the radicals necessary for the chain growth process 2→4, i.e. via the photo stimulation of individually active monomer molecules 2, e.g. (but not certain) in a state 2* to be described as “diradical”. In addition to a photo-induced polymerization, in which a direct activation of individual monomer molecules such as 2 into an active species such as 2* triggering the polymerization which occurs via light of a wavelength, preferably in the range of 150 nm to 700 nm, indirect photoinitiation is also alternatively suitable to occur.

The electromagnetic radiation from the range of wavelengths already stated, preferably 150 nm to 700 nm, is hereby used. In case of light of a greater wave and/or in case of an absence of suitable absorption bands in the molecules to be polymerized in particular, sensitizers are also suitable to be utilized. In addition, is the possibility of triggering polymerization via photoinitiators is claimed in the sense of the invention; these photoinitiators are suitable to be used either individually or in combination with a sensitizer.

In an advantageous embodiment of the method according to the present invention, the solution from 2 is initially irradiated with short-wavelength UV light for a short period of time, so that part of the molecules is activated from 2 to 2* and polymerized to the intermediate 4, where the reaction then remains under suitable reaction control. “Suitable reaction control” hereby means that 4 is stored at a temperature lower than or equal to −80° C. At temperatures lower than or equal to −80° C., thermally induced dehydrohalogenization from 4 to 5 does not occur. 4 is then suitable to subsequently be converted to 5 via a temporally and/or spatially separate process. This conversion is suitable to occur either thermally via warming or by means of irradiation. The thermal conversion of 4 to 5 requires temperatures of higher than or equal to −70° C. If the dehydrohalogenization from 4 to 5 occurs in a photo-induced manner, this already proceeds at temperatures lower than or equal to −80° C. Light in the UV or visible spectrum is suitable for photo inducement. The conversion from 4 to 5 particularly preferably occurs in a photo-induced manner via irradiation with light in the visible spectrum.

The embodiment mentioned, wherein the reaction initially stops at intermediate 4, is particularly advantageous if the dehydrohaolgenized end product 5 is difficult to dissolve, because the corresponding intermediate 4 normally comprises a different solubility behavior.

Furthermore, with the exposure of a monomer solution deposited on a carrier substrate by means of a print or coating method via a photomask which covers certain areas of the carrier, a photostructuring of the polymer to be deposited is possible. A polymer is therefore only suitable to be produced in certain areas on the carrier. By means of a subsequent washing process, unexposed areas of the monomer are suitable to be cleaned. In a further arrangement possibility of the method according to the present invention, instead of the active monomer itself, the starting materials available in solution (e.g. bishalomethylene-substituted aromatic compounds and heteroaromatic compounds) with the excipients (solvent, base) are also suitable to be deposited on the carrier, converted into the active monomer species and then suitable to be polymerized according to the conditions stated above.

In case the yielding polymers are insoluble, the coating process based on the method according to the present invention is suitable to be repeated several times with the same or other polymers as well. Use of the same solvent is also suitable. In doing so, several semiconducting polymer layers are suitable to be deposited either one next to the other or on top of one another on a carrier substrate without the necessity of a subsequent cross-linking, e.g. via reactive groups in the side chains of the polymers. Such a realization of several layers is, by way of non-exhaustive example, of interest to organic solar cells, transistors (OFETs) and light emitting diodes (OLEDs) and the combination thereof.

By way of non-exhaustive example, tetrahydrofurane, dioxane, diethylether, methyl-tert-butylether, cyclohexanone, acetonitrile, toluene, xylenes, anisole, chlorobenzene, pentane, 2,2,4-trimethylpentane and methylenechloride are used individually or in combination as solvents. It is important that the solvents do not react in an interfering manner at the required temperatures, that they remain as liquid, and that the monomers stay dissolved in the solvents.

The deposition of the monomer on the carrier is, by way of non-exhaustive example, suitable to be achieved by means of squeegees, dip, spray, spin coating, inkjet printing, screen printing methods, or offset, high, flat, gravure printing and silk screen printing.

With this method and apparatus, displays such as OLEDs, O-TFTs, OFETs or solar cells are, by way of non-exhaustive example, suitable to be produced on fixed (e.g. glass) or flexible (e.g. plastics, PET) carriers.

### EMBODIMENTS

A prepared carrier, for example glass or plastic film (e.g. PET) is cooled under inert gas to −80° C. A solution cooled to −90° C. from dry and degassed solvent, for example THF, is coated or printed on the carrier together with the starting material, e.g. 1,4-bis(brommethylene)-2,5-bis(2′ethylhexyloxy)benzene and one base, e.g. potassium-tert-butylate. The layer thickness results from the amount of the solution deposited, or is adjusted by means of, for example, spin dip, spray coating or squeegees. The photochemical polymerization is carried out via an UV lamp, e.g. a quicksilver lamp (wavelength 254 nm; with edge filter if required), (O)LEDs, laser or a UV light (400 nm) emitting light bulb, wherein a photomask is suitable to be introduced into the beam path if required. Subsequent to the photo-induced polymerization at −90° C., it is washed with possibly cooled solvent (in the case of a precipitation polymerization) or a precipitant (in the case of soluble polymers). The carrier coated in this manner with the polymer is now suitable to be further processed.

1. Method for the production of semiconducting polymers in general of the class of the poly(arylene-vinylenes), wherein the polymerization is triggered by electromagnetic (or particle)radiation with a wavelength of 150 nm to 700 nm.

2. A method according to claim 1, wherein on a carrier
a. starting material or monomer is deposited,
b. the polymerization is triggered photochemically,
c. residue starting material or monomer is removed.

3. Method according to claim 1, wherein the starting material or monomer is deposited or dissolved at a temperature of −30° C. to −200° C., preferably −50° C. to −200° C., particularly preferably −80° C. to −200° C., in particular −90° C. to −120° C.

4. Method according to claim 1, wherein the layer thickness is adjusted either during or subsequent to the deposition of the starting material or monomer.

5. Method according to claim 1, wherein substituted aromatic compounds and heteroaromatic compounds are used as starting materials, wherein the aromatic compound or heteroaromatic compound comprises structures such as phenyl, biphenyl, fluorine, stilbene, alpha-phenylcinnamonitrile, 3-amino-2,3-diphenyl-acrylonitrile, alpha,beta-diphenylfumaronitrile, thienyl, naphtyl, triazine, triazole, oxadiazole, pyridine, quinoline.

6. Method according to claim 1 wherein the starting material which is substituted comprises groups such as
—H, —CH3, alkyl, alkoxy, aryl, aryloxy; acceptors such as —CN, —SCN, —N⁺(R⁹)₃ (e.g. halide, dicyanamide, CN⁻, bis(trifluoromethylsulfonyl)amide); donors such as —N(R⁹)ₙ, wherein n=1 to 2 with R⁹═H, methyl, ethyl, n-propyl, isopropyl, 1-butyl, 2-butyl, tert-butyl; and
—OR¹⁰ or —R¹⁰, wherein
R¹⁰=linear or branched alkyl (methyl, ethyl, n-propyl, iso-propyl, n-butyl, iso-butyl, sec-butyl, tert-butyl, n-pentyl, iso-pentyl, sec-pentyl, neo-pentyl, 1,2-dimethylpropyl, iso-amyl, n-hexyl, iso-hexyl, sec-hexyl, n-heptyl, iso-heptyl, n-octyl, n-decyl, 1-nonyl, 1-decyl),
R¹⁰=aryl (e.g. phenyl, biphenyl, fluorene, pyrene, tolyl, mesityl, cyclopentadienyl, naphthalene, anthracene),
R¹⁰=heteroaryl (e.g. pyridyl, thiophene, pyrazole, imidazole, carbazole, oxadiazole, furyl) and in combinations therefrom.

7. Device with electroluminescent polymers, wherein the polymer comprises poly(arylene-vinylene), wherein aryl comprises structures such as phenyl, biphenyl, fluorine, stilbene, alpha-phenylcinnamonitrile, 3-amino-2,3-diphenyl-acrylonitrile, alpha,beta-diphenylfumaronitrile, thienyl, naphtyl, triazine, triazole, oxadiazole, pyridine, quinoline.

8. Device according to claim 7, wherein the substituents of the poly(arylene-vinylene) comprise structures such as —H, —CH₃, alkyl, alkoxy, aryl, aryloxy; acceptors such as —CN, —SCN, —N+(R⁹)₃ (e.g. halide, dicyanamide, CN⁻, bis(trifluoromethylsulfonyl)amide); donors such as —N(R⁹)ₙ, wherein n=1 to 2 with R⁹═H, methyl, ethyl, n-propyl, isopropyl, 1-butyl, 2-butyl, tert-butyl; and
—OR¹⁰ or —R¹⁰, wherein
R¹⁰=linear or branched alkyl (methyl, ethyl, n-propyl, iso-propyl, n-butyl, iso-butyl, sec-butyl, tert-butyl, n-pentyl, iso-pentyl, sec-pentyl, neo-pentyl, 1,2-Dimethylpropyl, iso-amyl, n-hexyl, iso-hexyl, sec-hexyl, n-heptyl, iso-heptyl, n-octyl, n-decyl, 1-Nonyl, 1-Decyl),
R¹⁰=aryl (e.g. phenyl, biphenyl, fluorene, pyrene, tolyl, mesityl, cyclopentadienyl, naphthalene, anthracene),
R¹⁰=heteroaryl (e.g. pyridyl, thiophene, pyrazole, imidazole, carbazole, oxadiazole, furyl) and in combinations therefrom.

9. In a method of producing displays, LEDs, OLEDs, semiconductors such as transistors and OFETs, and/or solar cells, the improvement comprising using the device of claim 7 for said producing step.
